(19) United States
(12) Patent Application Publication
(10) Pub. No.: US 2024/0006370 A1
(43) Pub. Date: Jan. 4, 2024

(54) CHIP PACKAGE WITH HEAT DISSIPATION PLATE AND MANUFACTURING METHOD THEREOF

(71) Applicant: STATS ChipPAC Semiconductor (Jiangyin) Co., LTD., Wuxi City (CN)

(72) Inventors: ZELONG YU, Wuxi City (CN); HONGDE DAI, Wuxi City (CN); JIAN XU, Wuxi City (CN)

(21) Appl. No.: 18/213,960

(22) Filed: Jun. 26, 2023

(30) Foreign Application Priority Data
Jun. 29, 2022 (CN) 202210760757.5

(51) Int. Cl. H01L 23/00; H01L 23/367; H01L 21/56

(52) U.S. Cl. CPC H01L 24/73; H01L 2224/92125; H01L 21/563; H01L 24/13; H01L 24/14; H01L 24/16; H01L 24/29; H01L 24/32; H01L 24/33; H01L 24/81; H01L 24/83; H01L 24/92; H01L 2224/13082; H01L 2224/1403; H01L 2224/14181; H01L 2224/16227; H01L 2224/16245; H01L 2224/2929; H01L 2924/0665; H01L 2224/29339; H01L 2224/29347; H01L 2224/32225; H01L 2224/32245; H01L 2224/73204; H01L 2224/73253; H01L 2224/81193; H01L 2224/81191; H01L 2224/831; H01L 2224/83192; H01L 2224/9211; H01L 23/3675

(57) ABSTRACT

The present invention provides a chip packaging structure having a heat dissipation plate and a manufacturing method thereof. The packaging structure includes a substrate; at least one chip, disposed on a first surface of the substrate; the heat dissipation plate is bonded to the first surface, the heat dissipation plate and the substrate form a cavity in a surrounding manner for holding the chip therein, the heat dissipation plate and the chip are connected by at least one fixed connector, a thermal interface material is filled in a region among the heat dissipation plate, the chip and the fixed connector, and a connection strength between the fixed connector and the chip or the heat dissipation plate is greater than a connection strength between the thermal interface material and the chip or the heat dissipation plate. Thus, the connection strength between the chip and the heat dissipation plate is increased.

### TECHNICAL FIELD

The present invention relates to the field of electronic packaging technologies, and in particular to a chip packaging structure having a heat dissipation plate and a manufacturing method thereof.

### BACKGROUND

In a packaging structure, a heat dissipation plate is mainly used to protect a chip and conduct heat. The chip and the heat dissipation plate are connected by a thermal interface material, and the thermal conductivity of the thermal interface material is determined by its own material characteristics and coverage rate. Generally, the higher the thermal conductivity and the larger the coverage rate of the thermal interface material are, the more excellent the heat radiation performance of the packaging structure is.

However, in a manufacturing process and a reliability experiment of the packaging structure, delamination exists among the chip, the thermal interface material and the heat dissipation plate caused by a difference in warpage degrees of the chip and the heat dissipation plate due to their different thermal expansion coefficients, resulting in a failure of the chip packaging structure.

### SUMMARY

An object of the present invention is to provide a chip packaging structure having a heat dissipation plate and a manufacturing method thereof.

The present invention provides a chip packaging structure having a heat dissipation plate. The chip packaging structure includes:
a substrate having a first surface and a second surface opposite to each other;
at least one chip disposed on the first surface of the substrate and electrically connected to the substrate; and
the heat dissipation plate bonded to the first surface of the substrate, wherein the heat dissipation plate and the substrate form a cavity in a surrounding manner for holding the chip therein, the heat dissipation plate and the chip are connected by at least one fixed connector, a thermal interface material is filled in a region among the heat dissipation plate, the chip and the fixed connector, and a connection strength between the fixed connector and the chip or the heat dissipation plate is greater than a connection strength between the thermal interface material and the chip or the heat dissipation plate.

As a further improvement of the present invention, the heat dissipation plate and the chip are connected by a plurality of fixed connectors, and the fixed connectors are at least distributed at an edge of a non-functional surface of the chip.

As a further improvement of the present invention, the fixed connectors at least include first fixed connectors and second fixed connectors, a connection strength between the first fixed connectors and the chip or the heat dissipation plate is greater than a connection strength between the second fixed connectors and the chip or the heat dissipation plate, the first fixed connectors are distributed at four corners and/or four sides of the non-functional surface of the chip, and the second fixed connectors are distributed in a region between the first fixed connectors on two opposite sides.

As a further improvement of the present invention, an area of a fixed connection region between the first fixed connectors and the chip or the heat dissipation plate is larger than an area of a fixed connection region between the second fixed connectors and the chip or the heat dissipation plate.

As a further improvement of the present invention, the fixed connector is a bonded metal block disposed between the chip and the heat dissipation plate.

As a further improvement of the present invention, the chip has a functional surface towards the first surface of the substrate and a non-functional surface opposite to the functional surface, and at least one chip-side metal block is disposed on the non-functional surface of the chip.

As a further improvement of the present invention, the heat dissipation plate includes a top cover plate and a side cover plate extending downward along an edge of the top cover plate, the top cover plate is bonded above the non-functional surface of the chip, a tail end of the side cover plate is connected to the first surface of the substrate, at least one cover plate-side metal block is disposed on an inner surface of the top cover plate, the position and the number of the at least one cover plate-side metal block are set corresponding to those of the at least one chip-side metal block, and the cover plate-side metal block and the chip-side metal block are bonded to form the bonded metal block.

As a further improvement of the present invention, the heat dissipation plate is a metal heat dissipation plate.

As a further improvement of the present invention, a solder ball is disposed on the functional surface of the chip, the functional surface of the chip is electrically connected to a bonding pad on the first surface of the substrate through the solder ball, and an underfill is filled between the chip and the substrate.

The present invention further provides a manufacturing method of a chip packaging structure having a heat dissipation plate. The manufacturing method includes the following steps of:
providing a chip, and disposing at least one chip-side metal block on a non-functional surface of the chip;
providing a heat dissipation plate, and disposing at least one cover plate-side metal block on an inner surface of a top cover plate of the heat dissipation plate;
providing a substrate, disposing the functional surface of the chip towards a first surface of the substrate, and electrically connecting the functional surface of the chip and the first surface of the substrate;
coating the inner surface of the top cover plate of the heat dissipation plate with a thermal interface material; and
bonding the heat dissipation plate to the substrate, and fusion-bonding the cover plate-side metal block and the chip-side metal block.

As a further improvement of the present invention, disposing at least one chip-side metal block on the non-functional surface of the chip specifically includes:
disposing a plurality of chip-side metal blocks on the non-functional surface of the chip, and at least disposing the chip-side metal blocks at an edge of the non-functional surface of the chip.

As a further improvement of the present invention, disposing at least one chip-side metal block on the non-functional surface of the chip further includes:
disposing first chip-side metal blocks at four corners and/or four sides of the non-functional surface of the chip, and disposing second chip-side metal blocks in a region between the first chip-side metal blocks on two opposite sides, wherein an area of a fixed connection region between the first chip-side metal blocks and the chip is larger than an area of a fixed connection region between the second chip-side metal blocks and the chip.

As a further improvement of the present invention, disposing at least one cover plate-side metal block on the inner surface of the top cover plate of the heat dissipation plate specifically includes:
disposing the at least one heat dissipation plate-side metal block with the same number as and having a corresponding position with the at least one chip-side metal block on the inner surface of the top cover plate of the heat dissipation plate.

The present invention has the following beneficial effects. In the present invention, the fixed connectors with the connection strength higher than that of the thermal interface material is disposed between the heat dissipation plate and the chip, thereby increasing the connection strength between the chip and the heat dissipation plate, and reducing the warpage and deformation between the chip and the heat dissipation plate. Further, the fixed connector serving as a stress concentration region has a higher structural strength, and is capable of bearing a stronger deformation force, thereby reducing a risk of delamination of the thermal interface material and improving the reliability of the chip packaging structure. In addition, the fixed connectors increase the connection strength between the chip and the heat dissipation plate, such that a heat-radiating adhesive with a high thermal conductivity can be used to further improve the heat conduction efficiency between the chip and the heat dissipation plate.

### BRIEF DESCRIPTION OF THE DRAWINGS

FIG. 1 is a schematic structural diagram of a packaging structure having a heat dissipation plate according to an embodiment of the present invention;

FIG. 2 is a schematic flowchart of a manufacturing method of a packaging structure having a heat dissipation plate according to an embodiment of the present invention; and

FIG. 3 to FIG. 7 are schematic diagrams of steps of a manufacturing method of a packaging structure having a heat dissipation plate according to an embodiment of the present invention.

### DETAILED DESCRIPTION

In order to make the objects, technical solutions, and advantages of the present application clearer, the technical solutions of the present application will be clearly and completely described below in conjunction with the specific embodiments and the corresponding accompanying drawings of the present application. Obviously, the described embodiments are only a part of the embodiments of the present application, rather than all of the embodiments. Based on the embodiments in present application, all other embodiments obtained by those of ordinary skill in the art without creative work shall fall within the protection scope of the present application.

The following describes the embodiments of the present invention in detail. Examples of the embodiments are shown in the accompanying drawings, in which the same or similar reference numerals indicate the same or similar elements or elements with the same or similar functions throughout the Description. The following embodiments described with reference to the accompanying drawings are exemplary and only used to explain the present invention, but should not be understood as limiting the same.

For the convenience of description, the terms representing relative positions in space, such as “upper”, “lower”, “rear” and “front” are used herein for description, and intended to describe a relationship of one unit or feature shown in the drawings relative to another unit or feature. The terms representing the relative positions in space may include different orientations of a device in use or operation other than the orientations shown in the drawings. For example, if an apparatus in the drawing is turned over, the unit described as being “below” or “above” another unit or feature will be positioned “above” or “below” the other units or features. Therefore, the exemplary term “below” can encompass both spatial orientations of “below” and “above”.

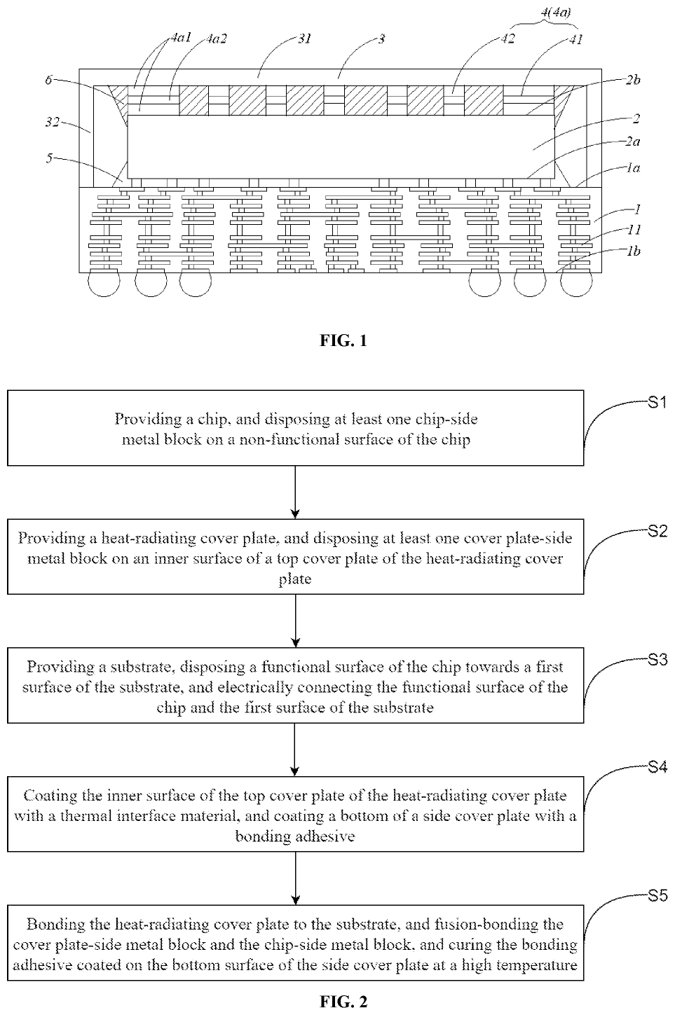

As shown in FIG. 1, a chip packaging structure having a heat dissipation plate is provided according to an embodiment. The chip packaging structure includes: a substrate 1, at least one chip 2 and a heat dissipation plate 3. The heat dissipation plate 3 and the chip 2 are connected by a fixed connector 4. Compared with a direct connection between the heat dissipation plate 3 and the chip 2 through a thermal interface material 6, the connection through the fixed connector 4 increases a bonding force between the heat dissipation plate 3 and the chip 2, restrains the warpage and deformation between the chip 2 and the heat dissipation plate 3, and reduces a risk of delamination of the thermal interface material 6.

The substrate 1 has a first surface 1a and a second surface 1b opposite to each other. In this embodiment, a bonding pad for forming an electrical connection with the chip 2 is disposed on the first surface 1a of the substrate, and a conductive connection structure such as a solder ball for forming an electrical connection with an externally-connected circuit or another chip 2 is disposed on the second surface 1b of the substrate. At least one metal wiring layer 11 is disposed inside the substrate 1, and the bonding pad and the solder ball are electrically communicated through the metal wiring layer 11.

At least one chip 2 is disposed on the first surface 1a of the substrate and electrically connected to the substrate 1. In this embodiment, one chip 2 is disposed on the substrate 1, and the chip 2 has a functional surface 2a and a non-functional surface 2b opposite to each other. The functional surface 2a of the chip is provided with a conductive connection structure such as the solder ball, faces the first surface 1a of the substrate, and is flip-mounted on and electrically connected to the substrate 1. An underfill 5 is filled between the chip 2 and the substrate 1 to reduce stress between the substrate 1 and the chip 2 resulted from the mismatch of thermal expansion coefficients and to further protect the solder ball of the chip 2 and the surface of the substrate 1.

In other embodiments of the present invention, a plurality of chips 2 and other passive electronic components may also be disposed on the substrate 1, and the chips 2 may be disposed on the second surface 1b of the substrate 1 to form a double-sided packaging structure, thereby improving the integration of a single packaging structure. In addition to the flip-mounting, the chips 2 may also be disposed on the substrate 1 by up-tight mounting, or the like. Further, a groove may be formed in the substrate 1, and the chips 2 are embedded in the groove of the substrate 1, which is not limited in the present invention. In a word, the chips 2 and the substrate 1 may be disposed with the known packaging structure of the chip 2 in the prior art.

The heat dissipation plate 3 is bonded to the first surface 1a of the substrate and fixedly disposed on the substrate 1 with a bonding adhesive, and the heat dissipation plate 3 and the substrate 1 form a cavity in a surrounding manner for holding the chip 2 therein. The heat dissipation plate 3 and the chip 2 are connected by at least one fixed connector 4, the thermal interface material 6 is filled in a region among the heat dissipation plate 3, the chip 2 and the fixed connector 4, and a connection strength between the fixed connector 4 and the chip 2 or the heat dissipation plate 3 is greater than a connection strength between the thermal interface material 6 and the chip 2 or the heat dissipation plate 3.

The heat dissipation plate 3 may be made of a material with an excellent thermal conductivity such as copper, a heat-conducting ceramic, or a ceramic-metal composite material. The heat dissipation plate 3 covers the non-functional surface 2b of the chip 2 to conduct the heat and help the chip 2 to form a thermal interconnection with the outside, thereby assisting the chip 2 with heat radiation.

The thermal interface material 6 is a material coated between the heat dissipation plate 3 and the chip 2, and can reduce thermal contact resistance between the chip 2 and the heat dissipation plate 3. In the packaging structure of the chip 2, an epoxy-based heat-conducting adhesive containing an additive such as silver and copper may be used as the thermal interface material 6, which can reduce the thermal contact resistance and adhesively fix the chip 2 and the heat dissipation plate 3.

Specifically, in this embodiment, the heat dissipation plate 3 is a metal cover plate, and includes a top cover plate 31 and a side cover plate 32. The top cover plate 31 is a flat plate with a rectangular plane, and the side cover plate 32 is located on a circumferential side of the top cover plate 31, extends downward along an edge of the top cover plate 31, and is adhered on the substrate 1 with the bonding adhesive. The heat dissipation plate 3 is integrally formed into a box-shaped structure with a downward opening, and a lower surface of the top cover plate 31, an inner wall surface of the side cover plate 32 and an upper surface of the substrate 1 form a cavity in a surrounding manner for holding the chip 2 therein. The heat dissipation plate 3 having a certain structural strength and the box-shaped structure can help the chip 2 to radiate the heat and protect the chip 2. For example, the heat dissipation plate 3 enables the chip 2 to be less affected by harmful operation environments such as mechanical tension, shearing, twisting and vibration, and can prevent the chip 2 from being eroded by impurities such as water vapour and dust.

In other embodiments of the present invention, the heat dissipation plate 3 may also be of another structure with a longitudinal section in a shape of a trapezoid, or the like, as long as the heat dissipation plate 3 and the substrate 1 can form the cavity for holding the chip 2.

When the packaging structure of the chip 2 is in a cyclic process of reflow soldering and temperature testing, different thermal expansion coefficients among the thermal interface material 6, the chip 2 and the heat dissipation plate 3 may lead to different expansion or contraction degrees among the thermal interface material 6 the chip 2 and the heat dissipation plate 3, causing the concentration of thermal stress. As a result, a warpage degree between the chip 2 and the heat dissipation plate 3 is changed. In severe cases, delamination or cracking may occur among the chip 2, the thermal interface material 6 and the heat dissipation plate 3, thereby causing a failure of the packaging structure of the chip 2. In this embodiment, by disposing the fixed connector 4, the connection strength between the chip 2 and the heat dissipation plate 3 is increased, and the warpage and deformation between the chip 2 and the heat dissipation plate 3 are reduced. Further, the fixed connector 4 serving as the stress concentration region has the higher structural strength, and is capable of bearing a stronger deformation force, thereby reducing the risk of delamination of the thermal interface material 6 and improving the reliability of the packaging structure of the chip 2. In addition, the fixed connector 4 increase the connection strength between the chip 2 and the heat dissipation plate 3, such that the heat-radiating adhesive with the high thermal conductivity may be used as the thermal interface material 6 to further improve the heat conduction efficiency between the chip 2 and the heat dissipation plate 3.

Further, the heat dissipation plate 3 and the chip 2 are connected by a plurality of fixed connectors 4, and the fixed connectors 4 are at least distributed at an edge of the non-functional surface 2b of the chip 2. By disposing the plurality of fixed connectors 4, the connection strength between the chip 2 and the heat dissipation plate 3 can be further increased, and the stress can be dispersed to the plurality of fixed connectors 4, thereby reducing a risk of connection failure caused by a single fixed connector 4. Generally, since the warpage and deformation are gradually formed from the edge to the center of the non-functional surface 2b of the chip 2, the fixed connectors 4 at least disposed at the edge can restrain the warpage and deformation between the chip 2 and the heat dissipation plate 3 better.

Further, the fixed connector 4 at least includes first fixed connectors 41 and second fixed connectors 42, a connection strength between the first fixed connectors 41 and the chip 2 or the heat dissipation plate 3 is greater than a connection strength between the second fixed connectors 42 and the chip 2 or the heat dissipation plate 3, the first fixed connectors 41 are distributed at four corners and/or four sides of the non-functional surface 2b of the chip 2, and the second fixed connectors 42 are distributed in a region between the first fixed connectors 41 on two opposite sides. The first fixed connectors 41 with the higher connection strength disposed at four sides and/or four corners can further restrain the warpage and deformation between the chip 2 and the heat dissipation plate 3. The second fixed connectors 42 with the lower connection strength disposed in the central region can reduce production cost to some extent.

The above distribution manner is not limited. In other embodiments of the present invention, the first fixed connectors 41 and the second fixed connectors 42 may also be arranged in other manners. In addition to four sides and/or four corners, the first fixed connectors 41 may be additionally disposed in the central region of the chip 2 to enable the stress to be distributed more uniformly.

In this embodiment, an area of a fixed connection region between the first fixed connectors 41 and the chip 2 or the heat dissipation plate 3 is larger than an area of a fixed connection region between the second fixed connectors 42 and the chip 2 or the heat dissipation plate 3. By disposing the fixed connector 4 with a larger contact area, the connection strength can be higher. In other embodiments of the present invention, the first fixed connector 41 and the second fixed connector 42 may also be made of different materials.

Specifically, in this embodiment, the fixed connector 4 is a bonded metal block 4a. disposed between the chip 2 and the heat dissipation plate 3. The bonded metal block 4a includes base metal layers 4a1 bonded to the chip 2 and the heat dissipation plate 3 respectively and a bonding layer 4a2 located between the base metal layers 4a1. At least one chip-side metal block is disposed on the non-functional surface 2b of the chip 2. At least one cover plate-side metal block is disposed on an inner surface of the top cover plate 31, the position and the number of the at least one cover plate-side metal block are set corresponding to those of the at least one chip-side metal block, and the cover plate-side metal block and the chip-side metal block are bonded to form the bonded metal block 4a. Correspondingly, the heat dissipation plate 3 is a metal heat dissipation plate 3 that can be well bonded to the cover plate-side metal block.

In addition to the high structural strength and the high connection strength between the chip 2 and the heat dissipation plate 3, the bonded metal block 4a formed by fusion bonding also has an excellent thermal conductivity, and can further improve the heat radiation efficiency between the chip 2 and the heat dissipation plate 3.

In summary, in the present invention, the fixed connector 4 with the connection strength higher than that of the thermal interface material 6 is disposed between the heat dissipation plate 3 and the chip 2, thereby increasing the connection strength between the chip 2 and the heat dissipation plate 3, and reducing the warpage and deformation between the chip 2 and the heat dissipation plate 3. Further, the fixed connector 4 serving as the stress concentration region has the higher structural strength, and is capable of bearing a stronger deformation force, thereby reducing the risk of delamination of the thermal interface material 6 and improving the reliability of the packaging structure of the chip 2. In addition, the fixed connector 4 increases the connection strength between the chip 2 and the heat dissipation plate 3, such that the heat-radiating adhesive with the high thermal conductivity can be used to further improve the heat conduction efficiency between the chip 2 and the heat dissipation plate 3.

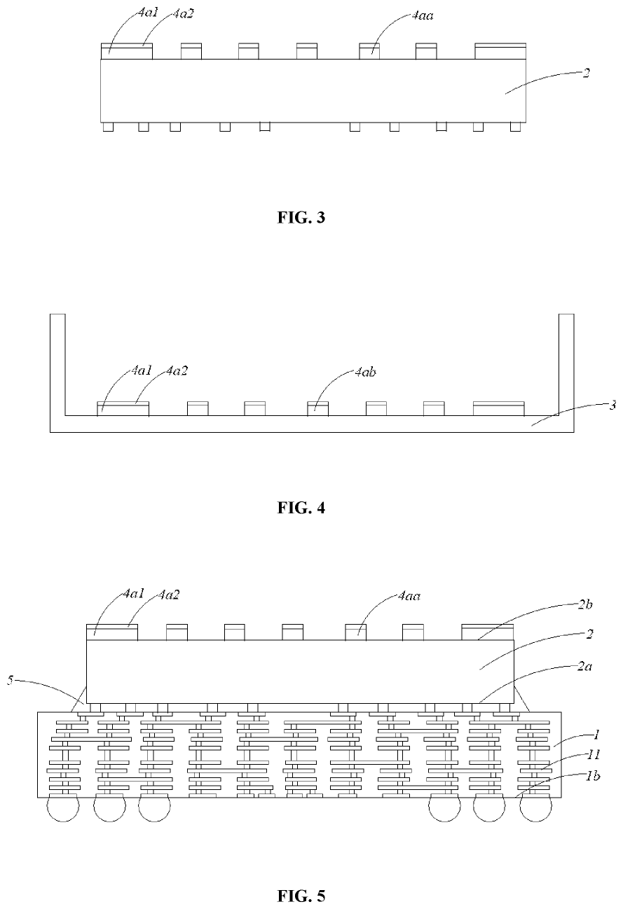

As shown in FIG. 2, based on the same invention concept, a manufacturing method of a chip packaging structure having a heat dissipation plate is further provided according to the embodiment of the present invention. The manufacturing method thereof includes the following steps.

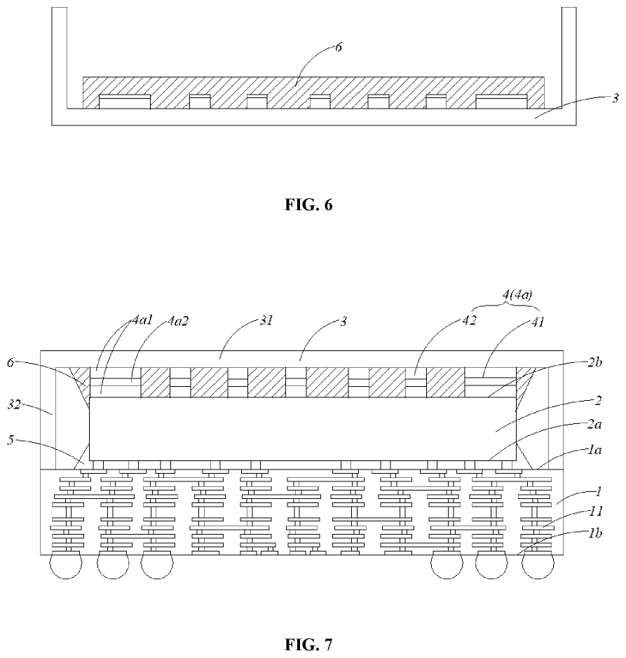

In S1, as shown in FIG. 3, a chip 2 is provided, and at least one chip-side metal block 4aa is disposed on a non-functional surface 2b of the chip 2.

In S2, as shown in FIG. 4, a metal heat dissipation plate 3 is provided, and at least one cover plate-side metal block 4ab is disposed on an inner surface of a top cover plate 31 of the heat dissipation plate 3.

In S3, as shown in FIG. 5, a substrate 1 is provided, and a functional surface 2a of the chip is disposed towards a first surface 1a of the substrate and electrically connected to the first surface 1a of the substrate.

In S4, as shown in FIG. 6, the inner surface of the top cover plate 31 of the heat dissipation plate 3 is coated with a thermal interface material 6.

In S5, as shown in FIG, 7. the heat dissipation plate 3 is bonded to the substrate 1, and the least one cover plate-side metal block 4ab and the at least one chip-side metal block 4aa are fusion-bonded.

Step S1 specifically includes:
disposing first chip-side metal blocks 4aa at four corners and/or four sides of the non-functional surface 2b of the chip 2, and disposing second chip-side metal blocks 4aa in a region between the first chip-side metal blocks 4aa on two opposite sides, wherein an area of a fixed connection region between the first chip-side metal block 4aa and the chip 2 is larger than an area of a fixed connection region between the second chip-side metal block 4aa and the chip 2.

The chip-side metal block 4aa includes a base metal layer 4a1 and a bonding layer 4a2 disposed on the base metal layer 4a1.

In some embodiments of the present invention, step S1 further includes:
disposing a passive electronic component on the substrate 1.

Step S2 specifically includes:
disposing the at least one cover plate-side metal block 4ab with the same number as and having a corresponding position with the at least one chip-side metal blocks 4aa on the inner surface of the top cover plate 31 of the heat dissipation plate 3.

The cover plate-side metal block includes a base metal layer 4a1 and a bonding layer 4a2 disposed on the base metal layer 4a1.

Step S3 specifically includes:
flip-mounting the functional surface 2a of the chip on the substrate 1 with the functional surface facing the substrate 1.

An underfill 5 is filled between the chip 2 and the substrate 1.

Step S4 further includes:
coating the bottom of a side cover plate 32 with a bonding adhesive.

Step S5 further includes:
curing the bonding adhesive coated on a bottom surface of the side cover plate 32 at a high temperature to adhesively fix the heat dissipation plate 3 and the substrate 1 while fusion-bonding the cover plate-side metal block 4ab and the chip-side metal block 4aa.

It is to be understood that although the present invention is described in terms of embodiments in this description, each of the embodiments is not intended to contain an independent technical solution. Such description manner of the description is merely intended for clarity, and those skilled in the art should regard the description as a whole. The technical solutions in various embodiments may also be combined properly to develop other embodiments that can be understood by those skilled in the art.

The series of detailed illustrations listed above are merely for specifically illustrating the feasible embodiments of the present invention, but not intended to limit the protection scope of the present invention. Any equivalent embodiments or variations made without departing from the technical spirit of the present invention shall fall within the protection scope of the present invention.

What is claimed is:

1. A chip packaging structure having a heat dissipation plate, comprising:
a substrate, having a first surface and a second surface opposite to each other;
at least one chip, disposed on the first surface of the substrate and electrically connected to the substrate; and
the heat dissipation plate, wherein the heat dissipation plate is bonded to the first surface of the substrate, the heat dissipation plate and the substrate form a cavity in a surrounding manner for holding the chip therein, the heat dissipation plate and the chip are connected by at least one fixed connector, a thermal interface material is filled in a region among the heat dissipation plate, the chip and the fixed connector, and a connection strength between the fixed connector and the chip or the heat dissipation plate is greater than a connection strength between the thermal interface material and the chip or the heat dissipation plate.

2. The chip packaging structure having a heat dissipation plate according to claim 1, wherein the heat dissipation plate and the chip are connected by a plurality of fixed connectors, and the fixed connectors are at least distributed at an edge of a non-functional surface of the chip.

3. The chip packaging structure having a heat dissipation plate according to claim 2, wherein the fixed connectors at least comprise first fixed connectors and second fixed connectors, a connection strength between the first fixed connectors and the chip or the heat dissipation plate is greater than a connection strength between the second fixed connectors and the chip or the heat dissipation plate, the first fixed connectors are distributed at four corners and/or four sides of the non-functional surface of the chip, and the second fixed connectors are distributed in a region between the first fixed connectors on two opposite sides.

4. The chip packaging structure having a heat dissipation plate according to claim 3, wherein an area of a fixed connection region between the first fixed connectors and the chip or the heat dissipation plate is larger than an area of a fixed connection region between the second fixed connectors and the chip or the heat dissipation plate.

5. The chip packaging structure having a heat dissipation plate according to claim 1, wherein the fixed connector is a bonded metal block disposed between the chip and the heat dissipation plate.

6. The chip packaging structure having a heat dissipation plate according to claim 5, wherein the chip has a functional surface towards the first surface of the substrate and a non-functional surface opposite to the functional surface, and at least one chip-side metal block is disposed on the non-functional surface of the chip.

7. The chip packaging structure having a heat dissipation plate according to claim 6, wherein the heat dissipation plate comprises a top cover plate and a side cover plate extending downward along an edge of the top cover plate, the top cover plate is bonded above the non-functional surface of the chip, a tail end of the side cover plate is connected to the first surface of the substrate, at least one cover plate-side metal block is disposed on an inner surface of the top cover plate, a position and a number of the at least one cover plate-side metal block are set corresponding to those of the at least one chip-side metal block, and the cover plate-side metal block and the chip-side metal block are bonded to form the bonded metal block.

8. The chip packaging structure having a heat dissipation plate according to claim 1, wherein the heat dissipation plate is a metal heat dissipation plate.

9. The chip packaging structure having a heat dissipation plate according to claim 1, wherein a solder ball is disposed on the functional surface of the chip, the functional surface of the chip is electrically connected to a bonding pad on the first surface of the substrate through the solder ball, and an underfill is filled between the chip and the substrate.

10. A manufacturing method of a chip packaging structure having a heat dissipation plate, comprising the following steps of:
providing a chip, and disposing at least one chip-side metal block on a non-functional surface of the chip;
providing a heat dissipation plate, and disposing at least one cover plate-side metal block on an inner surface of a top cover plate of the heat dissipation plate;
providing a substrate, disposing the functional surface of the chip towards a first surface of the substrate, and electrically connecting the functional surface of the chip and the first surface of the substrate;
coating the inner surface of the top cover plate of the heat dissipation plate with a thermal interface material; and
bonding the heat dissipation plate to the substrate, and fusion-bonding the cover plate-side metal block and the chip-side metal block.

11. The manufacturing method of a chip packaging structure having a heat dissipation plate according to claim 10, wherein disposing at least one chip-side metal block on the non-functional surface of the chip specifically comprises:
disposing a plurality of chip-side metal blocks on the non-functional surface of the chip, and at least disposing the chip-side metal blocks at an edge of the non-functional surface of the chip.

12. The manufacturing method of a chip packaging structure having a heat dissipation plate according to claim 11, wherein disposing at least one chip-side metal block on the non-functional surface of the chip further comprises:
disposing first chip-side metal blocks at four corners and/or four sides of the non-functional surface of the chip, and disposing second chip-side metal blocks in a region between the first chip-side metal blocks on two opposite sides, wherein an area of a fixed connection region between the first chip-side metal blocks and the chip is larger than an area of a fixed connection region between the second chip-side metal blocks and the chip.

13. The manufacturing method of a chip packaging structure having a heat dissipation plate according to claim 11, wherein disposing at least one cover plate-side metal block on the inner surface of the top cover plate of the heat dissipation plate specifically comprises:
disposing the at least one heat dissipation plate-side metal block with the same number as and having a corresponding position with the at least one chip-side metal block on the inner surface of the top cover plate of the heat dissipation plate.
